(19) United States
(12) Patent Application Publication
(10) Pub. No.: US 2013/0037821 A1
(43) Pub. Date: Feb. 14, 2013

(54) Semiconductor Device and Manufacturing Method thereof

(71) Applicants: Guilei Wang, Beijing (CN); Haizhou Yin, Poughkeepsie, NY (US)

(72) Inventors: Guilei Wang, Beijing (CN); Haizhou Yin, Poughkeepsie, NY (US)

(73) Assignee: INSTITUTE OF MICROELECTRONICS, CHINESE ACADEMY OF SCIENCE, Beijing (CN)

(21) Appl. No.: 13/320,581

(22) PCT Filed: Aug. 9, 2011
(86) PCT No.: PCT/CN11/01310

§ 371 Date: Nov. 15, 2011

(51) Int. Cl. H01L 29/78; H01L 21/336

(52) U.S. Cl. 257/77; 257/192; 438/285; 257/E29.255; 257/E21.409

(57) ABSTRACT

The present invention provides a semiconductor device, comprising: a substrate; shallow trench isolations embedded into the substrate and forming at least one opening area; a channel region located in the opening area; a gate stack comprising a gate dielectric layer and a gate electrode layer and located above the channel region; source/drain regions located at both sides of the channel region and comprising a stress layer that provides a strain to the channel region; wherein, there is a liner layer between the shallow trench isolation and the stress layer, which serves as the seed layer of the stress layer. A liner layer that is of the same or similar material as the stress layer in the source/drain region is inserted between the STI and the stress layer of the source/drain region as a seed layer or nucleation layer for the epitaxial growth, thereby eliminating the STI edge effect during the source/drain strain engineering, i.e. eliminating the gap between the STI and the stress layer of the source/drain region, as a result, the reduction of the channel stress produced by the source/drain strain is prevented, the carrier mobility of the MOS device is increased and the driving capability of the device is enhanced.

### CROSS REFERENCE

This application is a National Phase application of, and claims priority to, PCT Application No. PCT/CN2011/001310, filed on Aug. 9, 2011, entitled ‘Semiconductor Device and Manufacturing Method thereof’, which claimed priority to Chinese Application No. CN 201110029212.9, filed on Jan. 26, 2011. Both the PCT Application and Chinese Application are incorporated herein by reference in their entireties.

### FIELD OF THE INVENTION

The present invention relates to the field of semiconductor device, in particular to a semiconductor device with improved-epitaxial edges as well as the manufacturing method thereof.

### BACKGROUND OF THE INVENTION

The method of reducing costs by merely reducing the feature size has encountered a bottleneck at present, especially when the feature size is reduced to be under 150 nm, many physical parameters, such as the silicon forbidden band width Eg, the Fermi potential φ_{F}, the interface state and charge in the oxide layer Qox, the thermoelectric potential Vt and the pn junction built-in potential, cannot vary proportionally, which will influence the performance of the device that is reduced in size in proportion.

In order to further improve the device performance, stress has been introduced into the MOSFET channel region for improving the carrier mobility. For example, on a wafer having a crystal plane (100), the crystal orientation of the channel region is <110>, and in the PMOS, the stress along the direction of the horizontal axis (the source-drain direction) shall be a compression and the stress along the direction of the horizontal axis shall be a tension; while in the NMOS, the stress along the direction of the horizontal axis shall be a tension and the stress along the direction of the vertical axis shall be a compression. That is, the tension along the Source (S)-Drain (D) direction is introduced into the NMOS channel, while the compression along the S-D direction is introduced into the PMOS channel. The commonly used method of applying a compressive stress to the PMOS channel is to epitaxially grow SiGe stress layers on the source/drain region along the S-D direction. Since the lattice constant of the SiGe is greater than that of Si, the stress layers of S/D will apply a compressive stress to the channel region therebetween, which increases the hole mobility, and thereby increasing the drive current of the PMOS. Likewise, by epitaxially growing, on the source/drain region, Si:C stress layers whose lattice constant are smaller than that of Si, a tension can be provided to the NMOS channel.

However, since SiGe is epitaxially grown on Si selectively, different crystal planes have different epitaxial growth speeds. For example, the epitaxial growth of SiGe on the (111) crystal plane is slowest, so epitaxial growth of the SiGe has larger edge effect in the source/drain strain process integration.

FIGS. 1-6 show the schematic sectional views of epitaxially growing SiGe on the source/drain region according to the prior art.

First, as shown in FIG. 1, shallow trenches are formed by etching. FIG. 1A is the side profile of the device, and FIG. 1B is the top view of the device. In the following text, FIG. xA is a side profile and FIG. xB is the corresponding top view (x indicates a number), unless otherwise specified. A pad oxide layer or a silicon nitride layer 2 is deposited on a substrate 1, and shallow trenches are formed by a conventional exposure and etching by means of mask, wherein the substrate crystal plane is (100), the crystal orientation of the channel region is <110>, the pad oxide layer or the silicon nitride layer 2 is usually a rectangle, which corresponds to the active region and is surrounded by the shallow trenches.

Second, as shown in FIG. 2, shallow trench isolations are formed by deposition. The shallow trenches formed by etching are filled with oxides, for example, silicon dioxide formed by CVD deposition or thermal oxidation, then the oxide layer is planarized through, for example, a Chemical Mechanical Polishing (CMP) method until the substrate 1 is exposed, thereby forming shallow trench isolations STI 3. Before filling the oxides, an STI liner layer (not shown) may be deposited in the shallow trenches, which is made of an oxide or a silicon nitride and is used as the stress liner layer for the subsequent selective epitaxial growth of SiGe or SiC.

Next, as shown in FIG. 3, a gate stack structure is formed. A gate dielectric layer 4 is deposited on the substrate 1, and the material of the gate dielectric layer 4 may be silicon oxide or a high-k material (e.g. hafnium oxide) or the like; a gate electrode layer 5 is deposited on the gate dielectric layer 4, and the material of the gate electrode layer 5 may be polysilicon or metal; a gate stack structure is formed by exposure and etching by means of mask; and an insulating isolation layer such as silicon nitride is deposited on the entire structure and etched to leave an isolation spacer 6 only around the gate stack structure.

Then, as shown in FIG. 4, source/drain recesses are formed by photolithography, which is located at the inner side of STI 3 and at both sides of the isolation spacer 6 and is corresponding to the source/drain region of the PMOS to be formed subsequently.

Afterwards, as shown in FIG. 5, a SiGe stress layer 7 is epitaxially grown. The material of the STI liner layer is not the same or similar to that of the epitaxial layer 7, so it cannot serve as the seed layer of the epitaxial layer 7, that is, the epitaxially grown SiGe or SiC layer still does not match the liner layer and the STI 3 in terms of the crystal lattice. In addition, since the growth of SiGe on the (111) plane is slowest, a tilt side, which is the (111) plane as shown in FIG. 5A, will be formed at the edge of STI 3, i.e. at the interface with the epitaxially grown SiGe. The gap between this side and the SiGe will reduce the compressive stress of the SiGe in the source/drain region, such that the hole mobility is reduced and the driving capability of the PMOS is weakened. FIG. 5C is a sectional view of the structure of FIG. 5 along the direction BB′ perpendicular to the source/drain. Likewise, unless otherwise specified, FIG. xC is the sectional view of the corresponding structure along the direction BB′ perpendicular to the source drain.

Finally, as shown in FIG. 6, a silicide is formed on the source/drain region. A metal made of Ni, Ti or Co is deposited on the epitaxially grown SiGe stress layer 7, then annealing is performed to form the corresponding metal silicide, and the unreacted metal is peeled off, as such, a contact layer 8 is left on the SiGe stress layer 7.

It can be seen from FIG. 6 that SiGe is much thinner at the edge of the shallow trench isolation STI, so the stress of the SiGe in the source drain region is reduced along both the horizontal axis AA′ direction and the vertical axis BB′ direction; the contact layer 8 of the silicide in the edge region may contact the silicon region at the bottom, which may very likely increase the junction leakage current. Similar to the PMOS, SiC will also become thinner at the STI edge of the NMOS, thereby reducing the driving capability.

In view of this, there is a need for a new type semiconductor device that can effectively provide a stress to enhance the CMOS driving capability and reduce the junction leakage current as well as the manufacturing method thereof.

### SUMMARY OF THE INVENTION

The object of the present invention is to prevent the stress reduction caused by a gap between the stress layer and the shallow trench isolation of the semiconductor device.

To this end, the present invention provides a semiconductor device, comprising: a substrate; shallow trench isolations embedded in said substrate and forming at least one opening area; a channel region located in the opening area; a gate stack including a gate dielectric layer and a gate electrode layer, which is located above said channel region; source/drain regions located at both sides of the channel region, which comprises a stress layer for providing a strain to the channel region; wherein there is a liner layer between the shallow trench isolation and the stress layer.

Wherein, with respect to the pMOSFET, the stress layer comprises an epitaxially grown Si₁₋ₓGeₓ, with respect to the nMOSFET, the stress layer comprises an epitaxially grown Si_{1-y}C_{y}, wherein both x and y are greater than 0 but smaller than 1. Said liner layer comprises Si₁₋ₓGeₓ, Si_{1-x-y}GeₓC_{y} or Si_{1-y}C_{y}, wherein both x and y are greater than 0 but smaller than 1, x is in the range of 0.15 to 0.7, y is in the range of 0.002 to 0.02. The liner layer has a thickness of 1-20 nm. Wherein, the stress area is flush with the top of the shallow trench isolations.

The present invention also provides a method for manufacturing a semiconductor device, comprising: forming shallow trenches in the substrate; epitaxially growing a liner layer selectively in the shallow trench; forming an isolation material on the liner layer in the shallow trenches to form shallow trench isolations, said shallow trench isolations surrounding at least one opening area; forming a gate stack in the opening area; forming source/drain regions at both sides of the gate stack, wherein a place between the source/drain regions under the gate stack serves as a channel region, and said source/drain regions comprise a stress layer for providing a strain to the channel region.

Wherein, with respect to the pMOSFET, the stress layer comprises an epitaxially grown Si₁₋ₓGeₓ, with respect to the nMOSFET, the stress layer comprises an epitaxially grown Si_{1-y}C_{y}, wherein both x and y are greater than 0 but smaller than 1. Said liner layer comprises Si₁₋ₓGeₓ, Si_{1-x-y}GeₓC_{y} or Si_{1-y}C_{y}, wherein both x and y are greater than 0 but smaller than 1, x is in the range of 0.15 to 0.7, y is in the range of 0.002 to 0.02. The liner layer has a thickness of 1-20 nm. Wherein, the stress layer is flush with the top of the shallow trench isolations. The isolation material is silicon dioxide. The steps of forming the source drain regions include: etching the substrate to form trenches for the source/drain regions, and epitaxially growing the stress layer in the trenches of the source/drain regions.

In the present invention, a liner layer that is of the same or similar material as the stress layer in the source/drain regions is inserted between the STI and the stress layer of the source/drain region as a seed layer or nucleation layer for the epitaxial growth, thereby eliminating the edge effect of STI, i.e. eliminating the gap between the STI and the stress layer of the source/drain region, as a result, the stress reduction is prevented, the carrier mobility of the MOS device is increased and the driving capability of the device is enhanced.

The object described in the present invention as well as other objects that are not mentioned herein are achieved within the scope of the independent claims of the present application. The embodiments of the present invention are defined in the independent claims, and the specific features are defined in the dependent claims.

### BRIEF DESCRIPTION OF THE DRAWINGS

The technical solution of the present invention will be described in detail below with reference to the drawings, wherein,

FIGS. 1-6 are sectional views of the steps of forming the stress layer of the MOS source/drain region in the prior art; and

FIGS. 7-11 are sectional views of the steps of forming the stress layer of the MOS source/drain region with a liner layer according to the present invention.

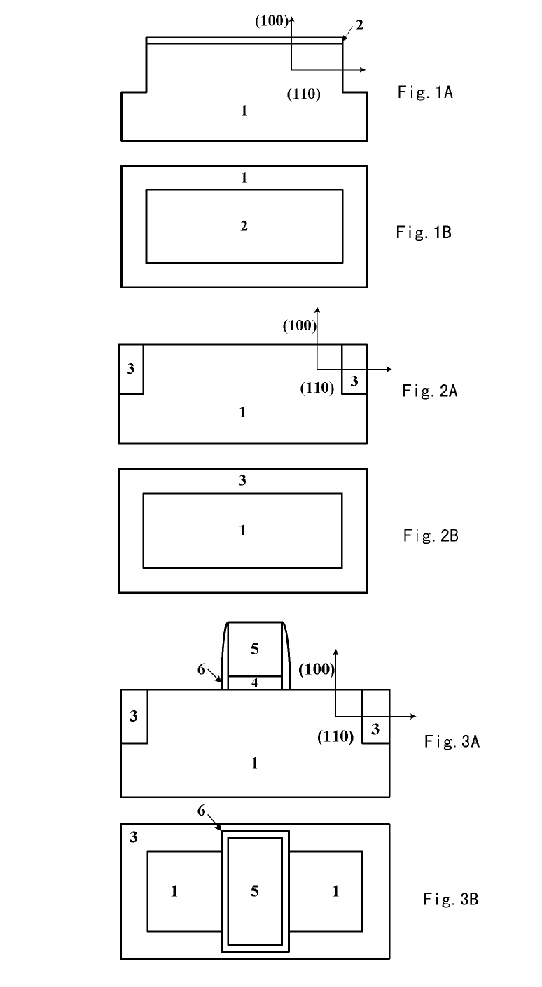

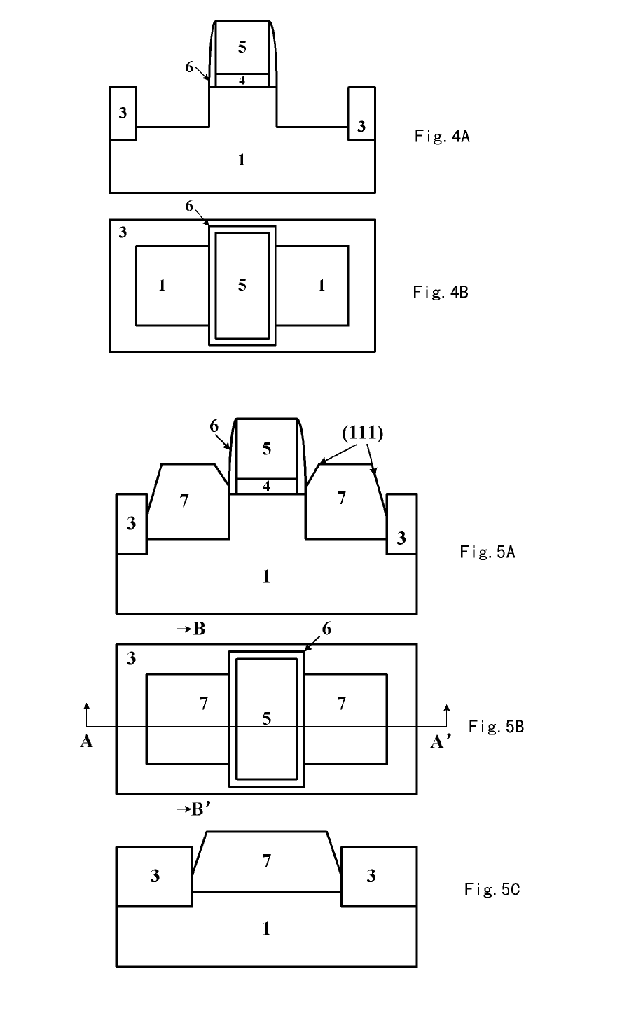

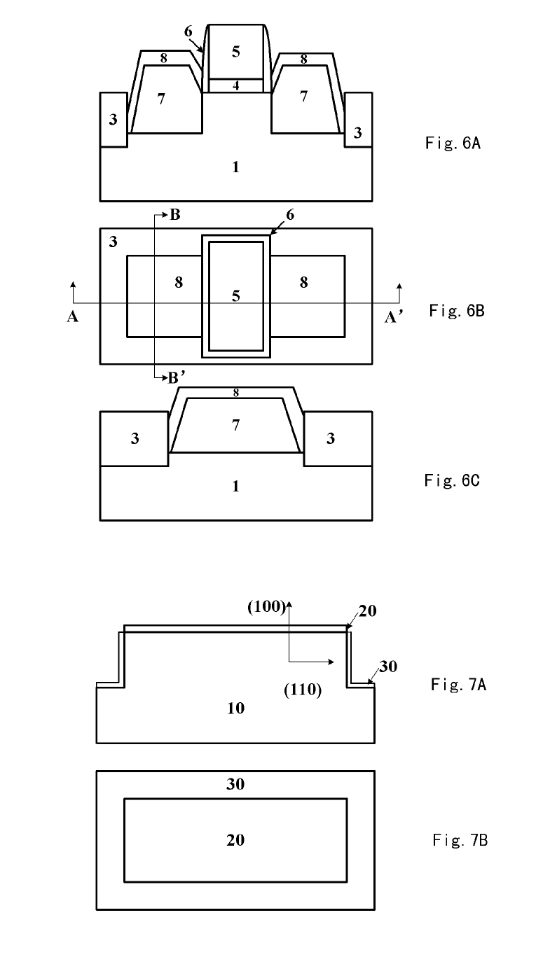

### DETAILED DESCRIPTION OF THE PREFERRED EMBODIMENTS

The features and technical effects of the technical solution of the present invention will be described in detail below with reference to the figures and in conjunction with the exemplary embodiments. It shall be noted that like reference signs indicate like structures; such terms as “first”, “second”, “above”, “under”, “thick” and “thin” used in this application can be used to define various device structures. But such qualifiers do not intend to imply the spatial, sequential or hierarchical relationship of the qualified device structure unless otherwise specified.

FIGS. 7-11 are schematic sectional views of epitaxially growing SiGe on the source/drain region according to the present invention.

First, as shown in FIG. 7, shallow trenches are formed by etching. A pad oxide layer 20 is deposited on a substrate 10, and the shallow trenches are formed by a conventional exposure and etching by means of mask. Wherein, the substrate 10 may be a bulk silicon or a Silicon-On-Insulator (SOI), or it may be such commonly used semiconductor substrate materials as SiGe, SiC and sapphire. The crystal plane of the substrate is (100), the crystal orientation of the channel region is <110>, the pad oxide layer 20 is usually a rectangle, which is corresponding to the active region and is surrounded by the shallow trenches. A thin layer of liner layer 30 is epitaxially grown selectively in the shallow trench using the pad oxide layer 20 as the mask, the liner layer 30 is made of such a material as Si₁₋ₓGeₓ, Si_{1-x-y}GeₓC_{y} or Si_{1-y}C_{y}, wherein both x and y are greater than 0 but smaller than 1, x may preferably be in the range of about 0.15 to 0.7, y may preferably be in the range of about 0.002 to 0.02. With respect to the PMOS, the liner layer 30 is preferably of the same material Si₁₋ₓGeₓ as the stress layer of the PMOS source/drain region; with respect to the NMOS, the liner layer 30 is preferably of the same material Si_{1-y}C_{y} as the stress layer of the NMOS source/drain region. The liner layer 30 functions as the nucleation layer or seed layer when epitaxially growing the stress layer of the source/drain region subsequently so as to completely fill the gap between the STI 40 and the stress layer of the source/drain region caused by the slow growth of SiGe on the (111) crystal plane. Said thin layer of liner layer 30 has a thickness of, for example, about 1-20 nm.

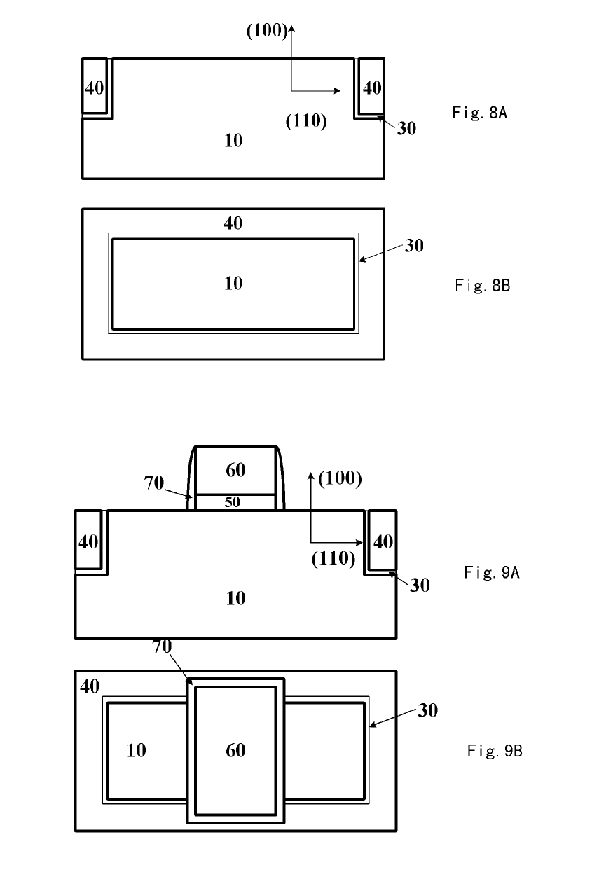

Then, as shown in FIG. 8, shallow trench isolations are formed by deposition. The pad oxide layer 20 is removed by means of hydrofluoric acid wet etching or fluorine-based gas plasma dry etching. The shallow trenches formed by etching are filled with an isolation material which can be an oxide, such as silicon dioxide formed by CVD deposition or by thermal oxidation, then the oxide layer is planarized by, for example, a Chemical Mechanical Polishing (CMP) method until the substrate 10 is exposed, thereby forming a shallow trench isolations (STI) 40.

Next, as shown in FIG. 9, a gate stack structure is formed. A gate dielectric layer 50 is deposited on the substrate 10, and the material of the gate dielectric layer 50 may be silicon oxide or high-k material (e.g. hafnium oxide) or the like; a gate electrode layer 60 is deposited on the gate dielectric layer 50, and the material of the gate electrode layer 60 may be polysilicon or metal; a gate stack structure is formed by exposure and etching by means of mask; an insulating isolation layer such as silicon nitride is deposited on the entire structure and etched to leave the isolation spacer 70 only around the gate stack structure.

Subsequently, as shown in FIG. 10, source/drain recesses are formed by exposure and anisotropic etching by means of mask, which are located at the inner side of the STI 40 and at both sides of the isolation spacer 6, and is corresponding to the source/drain region of the PMOS to be formed subsequently.

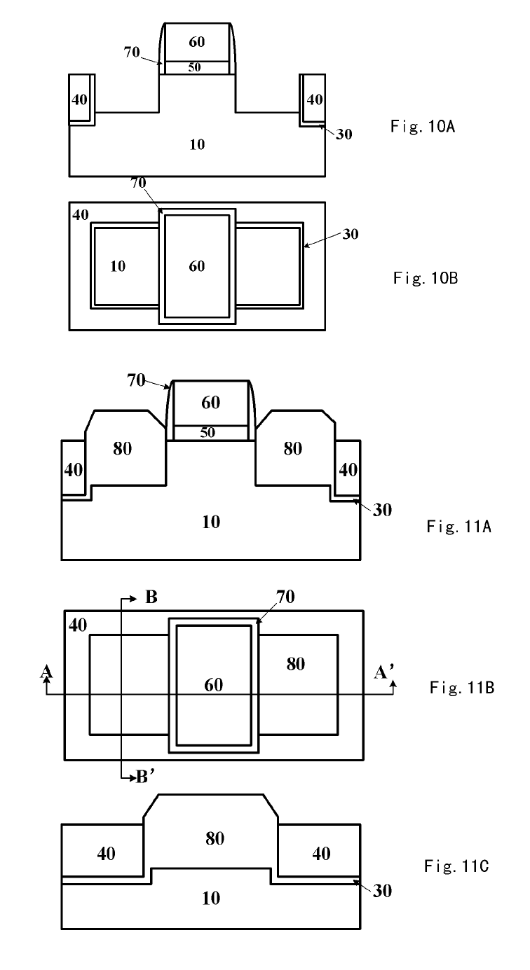

Afterwards, as shown in FIG. 11, a stress layer 80 is epitaxially grown to be used as the source/drain region of the device, that is, the stress layer 80 also serves as the source/drain region 80. Since the liner layer 30 is of the same or similar material as the stress layer 80, the gap that might exist is eliminated during the epitaxial growth, i.e. the STI edge effect is eliminated, thereby preventing the stress reduction, maintaining or increasing the carrier mobility and enhancing the MOS driving capability. Particularly, although the top surface of the epitaxially grown stress layer 80 is higher than the top surface of the STI 40 as shown in FIG. 11, preferably, the top surface of the stress layer 80 is substantially flush with the top surface of the STI 40 to prevent reduction of the actually applied stress caused by leakage of the stress from the place where the stress layer 80 is higher than the STI 40, thereby preventing reduction of the driving capability. With respect to the PMOS, the stress layer 80 may preferably be Si₁₋ₓGeₓ; with respect to the NMOS, the stress layer 80 may preferably be Si_{1-y}C_{y}, wherein both x and y are greater than 0 but smaller than 1, x may preferably be in the range of about 0.15 to 0.7 and y may preferably be in the range of about 0.002 to 0.02.

Finally, a silicide is formed on the stress layer 80 of the source/drain region. A metal made of Ni, Ti or Co is deposited on the epitaxially grown SiGe stress layer 80, then annealing is performed to form the corresponding metal silicide, and the un-reacted metal is peeled off, as such, a contact layer (not shown in FIG. 11) is left on the SiGe stress layer 80.

The finally formed device structure is as shown in FIG. 11: the shallow trench isolations (STI) 40 are located in the substrate 10, the STI 40 surround a semiconductor opening area, and the channel region of the device is located in said semiconductor opening area; the gate dielectric layer 50 is located above the channel region of the substrate 10, the gate electrode layer 60 is located on the gate dielectric layer 50, the gate dielectric layer 50 and the gate electrode layer 60 form a gate stack structure, and the isolation spacers 70 are located around the gate stack structure; the source/drain regions 80, i.e. the stress layer 80, are located at both sides of the gate stack structure and are formed of a material that can increase the stress. With respect to the PMOS, the stress layer 80 may preferably be Si₁₋ₓGeₓ; with respect to the NMOS, the stress layer 80 may preferably be Si_{1-y}C_{y}, wherein both x and y are greater than 0 but smaller than 1. There is a liner layer 30 between the source/drain regions 80 or the stress layer 80 and the STI 40, which is of the same or similar material as the stress layer 80, for example, Si₁₋ₓGeₓ, Si_{1-x-y}GeₓC_{y} or Si_{1-y}C_{y}, wherein both x and y are greater than 0 but smaller than 1, x may preferably be in the range of 0.15 to 0.7, y may preferably be in the range of 0.002 to 0.02. The top of the stress layer 80 may also have a metal silicide (not shown). In particular, the top of the stress layer 80 is flush with the top of the STI 40.

The process of forming the stress layer 80 of the source/drain region of the PMOS is disclosed above. With respect to the NMOS, the process steps are similar, and the only difference is that the material of the liner layer 30 is changed into Si_{1-y}C_{y} corresponding to the stress layer 80 of the source/drain of SiC.

The present invention has a liner layer inserted into the STI and the stress layer of the source/drain region as the seed layer or nucleation layer for the epitaxial growth, said pad layer being of the same or similar material as the stress layer of the source/drain region, such that the STI edge effect is eliminated, i.e. the gap between the STI and the stress layer of the source/drain region is eliminated, thereby preventing reduction of stress, increasing the carrier mobility of the MOS device, and enhancing the driving capability of the device.

While the invention has been described in conjunction with one or more exemplary embodiments, various appropriate changes and substitutions made to the method for forming the device structure without departing from the scope of the present invention will be apparent to those skilled in the art. In addition, many modifications that may be adapted to specific situations or materials can be made without departing from the scope of the present invention on the basis of the disclosed teaching. Therefore, the present invention is not intended to define the specific embodiments that are disclosed as the preferred ways of implementation of the present invention, but the disclosed device structure and the manufacturing method thereof will include all the embodiments that fall within the scope of the present invention.

What is claimed is:

1. A semiconductor device, comprising:
a substrate;
shallow trench isolations embedded into the substrate and forming at least one opening area;
a channel region located in the opening area;
a gate stack comprising a gate dielectric layer and a gate electrode layer, the gate stack being located above the channel region;
source/drain regions located at both sides of the channel region and comprising a stress layer that provides a strain to the channel region;
wherein, there is a liner layer between the shallow trench isolation and the stress layer, which serves as the seed layer of the stress layer.

2. The semiconductor device according to claim 1, wherein with respect to the pMOSFET, the stress layer comprises an epitaxially grown Si₁₋ₓGeₓ, and with respect to the nMOSFET, the stress layer comprises an epitaxially grown Si_{1-y}C_{y}, wherein x and y are both greater than 0 but smaller than 1.

3. The semiconductor device according to claim 1, wherein the liner layer comprises Si₁₋ₓGeₓ, Si_{1-x-y}GeₓC_{y} or Si_{1-y}C_{y}, wherein x and y are both greater than 0 but smaller than 1.

4. The semiconductor device according to claim 3, wherein x is in the range of 0.15 to 0.7, and y is in the range of 0.002 to 0.02.

5. The semiconductor device according to claim 1, wherein the liner layer has a thickness of 1-20 nm.

6. The semiconductor device according to claim 1, wherein the stress region is flush with the top of the shallow trench isolation.

7. A method for manufacturing the semiconductor device of claim 1, comprising:
forming shallow trenches in the substrate;
epitaxially growing a liner layer selectively in the shallow trench so as to be used as the seed layer of a stress layer;
forming an isolation material on the liner layer in the shallow trench to form shallow trench isolations, said shallow trench isolations surrounding at least one opening area;
forming a gate stack in the opening area;
forming source/drain regions at both sides of the gate stack, wherein a place between the source/drain regions under the gate stack serves as a channel region, and said source/drain regions comprise a stress layer for providing a strain to the channel region.

8. The method of claim 7, wherein, with respect to the pMOSFET, the stress layer comprises an epitaxially grown Si₁₋ₓGeₓ, with respect to the nMOSFET, the stress layer comprises an epitaxially grown Si_{1-y}C_{y}, wherein both x and y are greater than 0 but smaller than 1.

9. The method of claim 7, wherein said liner layer comprises Si₁₋ₓGeₓ, Si_{1-x-y}GeₓC_{y} or Si_{1-y}C_{y}, wherein both x and y are greater than 0 but smaller than 1.

10. The method of claim 9, wherein x is in the range of 0.15 to 0.7, y is in the range of 0.002 to 0.02.

11. The method of claim 7, wherein the liner layer has a thickness of 1-20 nm.

12. The method of claim 7, wherein the stress layer is flush with the top of the shallow trench isolation.

13. The method of claim 7, wherein the isolation material is silicon dioxide.

14. The method of claim 7, wherein the steps of forming the source/drain regions include: etching the substrate to form trenches for the source/drain regions, and epitaxially growing the stress layer in the trenches for the source/drain regions.
